(19) United States
(12) Patent Application Publication
(10) Pub. No.: US 2011/0235298 A1
(43) Pub. Date: Sep. 29, 2011

(54) Wiring substrate and method of manufacturing the wiring substrate

(75) Inventor: Shuuichi Kariyazaki, Kanagawa (JP)

(73) Assignee: RENESAS ELECTRONICS CORPORATION, Kawasaki-shi (JP)

(21) Appl. No.: 12/929,898

(22) Filed: Feb. 23, 2011

(30) Foreign Application Priority Data
Mar. 24, 2010 (JP) 2010-067894

(51) Int. Cl. H05K 7/02; H05K 1/11; H05K 3/10

(52) U.S. Cl. 361/783; 174/262; 29/846

(57) ABSTRACT

A wiring substrate includes a side-wall electroconduction layer and a land. The side-wall electroconduction layer is formed on the side-wall of a through hole formed in the substrate. The land is an electroconduction layer connected with the side-wall electroconduction layer in which only the land portion as a minimum necessary portion used for wiring is formed to the surface of the substrate. Unnecessary portion of the land other than the land portion is eliminated.

### CROSS-REFERENCE TO RELATED APPLICATION

The disclosure of Japanese Patent Application No. 2010-67894 filed on Mar. 24, 2010 including the specification, drawings and abstract is incorporated herein by reference in its entirety

### BACKGROUND

1. Field of the Invention

The present invention concerns a wiring substrate and a method of manufacturing the wiring substrate.

2. Description of Related Art

As one of embodiments, the wiring substrate includes a type in which through holes are formed in a substrate. The wiring substrate has a substrate, a side-wall electroconduction layers and lands. The side-wall electroconduction layer extends along the side-wall of a through hole opened in the substrate and reaches the surface of the substrate. The land is an electroconduction layer formed on the surface of the substrate and connected to the side-wall electroconduction layer. A signal line is connected over the land, for example, by way of a via.

When signals are transmitted at a high speed by way of the signal line, it has to be taken into consideration not only the reflection of the signals but also the rising (or falling) speed upon switching a signal level.

The signal rising (or falling) speed is physically determined by “time constant” represented by a multiplication product of a wiring resistance R and a wiring capacitance C. Accordingly, when it is intended to attain high speed signal transmission, it should be coped by lowering the wiring resistance or decreasing the wiring capacitance. Generally, this is coped by decreasing the wiring capacitance.

As the technique relevant to the wiring substrate, a technique of forming two or more wiring patterns by dividing a through hole, a side-wall electroconduction layer, and a land is described in Japanese Patent Application Publication Nos. Hei-10(1998)-51137, Sho-60(1985)-257585.

### SUMMARY

The following analyses are given by the present invention. In the technique described in Japanese Patent Application Publication No. Hei-10(1998)-51137, and Japanese Patent Application Publication No. Sho-60(1985)-257585, the through hole and the side-wall electroconduction layer are divided together with the land in order to attain high density and high integration degree of electronic equipment under the condition where the minimum diameter of the land is restricted.

However, since the density and the integration degree have been increased further, and the diameter of the through hole has been decreased in recent years, wiring capacitance cannot be decreased sufficiently by merely dividing the land.

The present invention seeks to solve one or more of the above problems, or to improve upon those problems at least in part.

A wiring substrate of the invention has a side-wall electroconduction layer and a land. The side-wall electroconduction layer is an electroconduction layer formed on the side-wall of a through hole opened in a substrate. The land is an electroconduction layer connected with the side-wall electroconduction layer and is formed on the surface of the substrate.

The side-wall electroconduction layer has a first side-wall electroconduction layer and a second side-wall electroconduction layer extending along the side-wall of the through hole. The first side-wall electroconduction layer reaches the surface of the substrate and is connected with the land. The second side-wall electroconduction layer is connected with the first side-wall electroconduction layer and does not reach the surface of the substrate. The second side-wall electroconduction layer is formed when an unnecessary portion of the land is eliminated.

According to the invention, the unnecessary portion of the land other than the land portion is eliminated. Accordingly, unnecessary wiring capacitance in the wiring capacitance due to the land and the side-wall electroconduction layer can be decreased by eliminating the unnecessary portion of the land while leaving only the minimum necessary portion used for the wiring in the land. Accordingly, “time constant” represented by the multiplication product of the wiring resistance R and the wiring capacitance C can be made sufficiently small to increase the signal rising (or falling) speed.

According to the invention, signals can be transmitted at high speed.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is an upper plan view showing a configuration of a wiring substrate according to a first embodiment of the invention;

FIG. 1B is a cross sectional view along line A-A′ in FIG. 1A;

FIG. 2 is a flow chart showing a method of manufacturing a wiring substrate according to a first embodiment of the invention;

FIG. 3A is a cross sectional view for explaining a through hole opening step (S1), a side-wall electroconduction layer formation step (S2), and a land formation step (S3) in FIG. 2;

FIG. 3B is an upper plan view for explaining a land formation step (S3) in FIG. 2;

FIG. 3C is a cross sectional view for explaining an unnecessary portion elimination step (S4) in FIG. 2;

FIG. 3D is an upper plan view for explaining an unnecessary portion elimination step (S4) in FIG. 2;

FIG. 3E a cross sectional view for explaining an unnecessary portion elimination step (S4) in FIG. 2;

FIG. 3F is a cross sectional view for explaining a hole filling step (S5) in FIG. 2;

FIG. 3G is a cross sectional view for explaining a via forming step (S11) and a signal line wiring step (S12) in FIG. 2;

FIG. 3H is an upper plan view of a wiring substrate in a case of eliminating an unnecessary portion by a method different from that in FIG. 3D;

FIG. 4A is an upper plan view showing the configuration of a wiring substrate according to a second embodiment of the invention;

FIG. 4B is a cross sectional view along line B-B′ in FIG. 4A;

FIG. 5 is a flow chart showing a method of manufacturing a wiring substrate according to the second embodiment of the invention;

FIG. 6A is a cross sectional view for explaining a through hole opening step (S1), a side-wall electroconduction layer formation step (S2), and a land formation step (S3) in FIG. 5;

FIG. 6B is an upper plan view for explaining a land formation step (S3) in FIG. 5;

FIG. 6C is a cross sectional view for explaining an unnecessary portion elimination step (S4) in FIG. 5;

FIG. 6D is an upper plan view for explaining an unnecessary portion elimination step (S4) in FIG. 5;

FIG. 6E is a cross sectional view for explaining a hole filling step (S5) in FIG. 5;

FIG. 6F is a cross sectional view for explaining a first wiring layer formation step (S21) and a plane formation step (S22) in FIG. 5;

FIG. 6G is a cross sectional view for explaining a via forming step (S23), a signal wiring step (S24), and a second wiring layer formation step (S25) in FIG. 4;

FIG. 7A is an upper plan view showing the configuration of a wiring substrate according to a third embodiment of the invention;

FIG. 7B is a cross sectional view along line C-C′ in FIG. 7A;

FIG. 8 is a flow chart showing a method of manufacturing a wiring substrate according to the third embodiment of the invention;

FIG. 9A is a cross sectional view for explaining a through hole opening step (S1), a side-wall electroconduction layer formation step (S2), and a land formation step (S3) in FIG. 7;

FIG. 9B is a side elevational view for explaining an unnecessary portion elimination step (S-4) in FIG. 7;

FIG. 9C is an upper plan view for explaining an unnecessary portion elimination step (S-4) in FIG. 7;

FIG. 9D is a cross sectional view for explaining a hole filling step (S5) in FIG. 7;

FIG. 9E is a cross sectional view for explaining a land portion elimination step (S31) in FIG. 7;

FIG. 9F is a cross sectional view for explaining a signal line wiring step (S32) in FIG. 7; and

FIG. 10 is an upper plan view for explaining the function and the effect of a wiring substrate according to the third embodiment of the invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes. The present invention is to be described in details for a wiring substrate according to preferred embodiments with reference to the accompanying drawings.

### First Embodiment

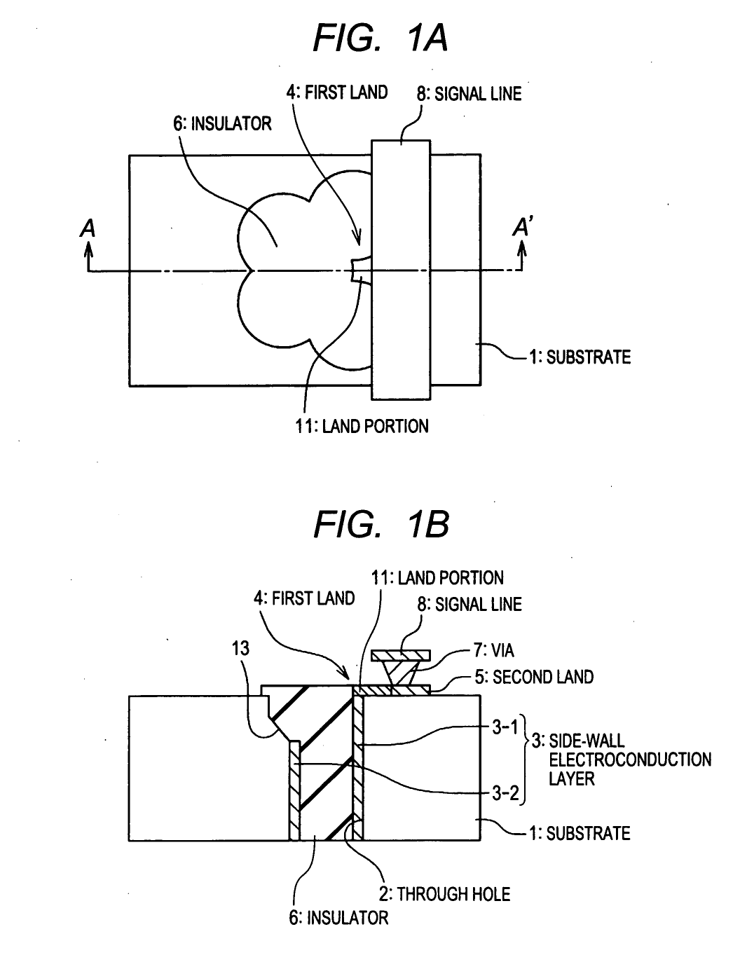

FIG. 1A is an upper plan view showing the configuration of a wiring substrate according to the first embodiment of the invention. FIG. 1B is a cross sectional view along line A-A′ in FIG. 1A. A wiring substrate according to the first embodiment of the invention includes a substrate 1, a side-wall electroconduction layer 3, a first land 4, a second land 5, an insulator 6, a via 7, and a signal line 8. Furthermore a semiconductor chip may be mounted onto the substrate 1 or the wiring substrate. In this case, a semiconductor device comprising the wiring substrate on which the semiconductor chip is mounted may be fabricated.

The side-wall electroconduction layer 3 is an electroconduction layer extending along the side-wall of a through hole 2 opened in the substrate 1. The side-wall electroconduction layer 3 includes a first block (hereinafter referred to as a first side-wall electroconduction layer 3-1) and a second block connected with the first side-wall electroconduction layer 3-1 (hereinafter referred to as a second side-wall electroconduction layer 3-2). The first side-wall electroconduction layer 3-1 reaches the surface of the substrate 1. The second side-wall electroconduction layer 3-2 does not reach the surface of the substrate 1.

The first land 4 is an electroconduction layer connected with the side-wall electroconduction layer 3 in which only the land portion 11 which is a minimum necessary portion used for the wiring is formed on the surface of the substrate 1. The first side-wall electroconduction layer 3-1 is connected with the land portion 11. The second side-wall electroconduction layer 3-2 is formed when an unnecessary portion of the first land 4 except for the land portion 11 (to be described later) is eliminated.

The second land 5 is an electroconduction layer formed on the surface of the substrate 1 and connected with the land portion 11.

The insulator 6 is a hole filling material covering the first side-wall electroconduction layer 3-1, the second side-wall electroconduction layer 3-2, and a scraped portion 13 of the substrate 1. A resin is used for the insulator 6.

The via 7 is formed over the second land 5. A signal line 8 is formed over the via 7. In the drawing, the insulation layer is not illustrated. Actually, the insulation layer (not illustrated) is present between the signal line 8 and the substrate 1.

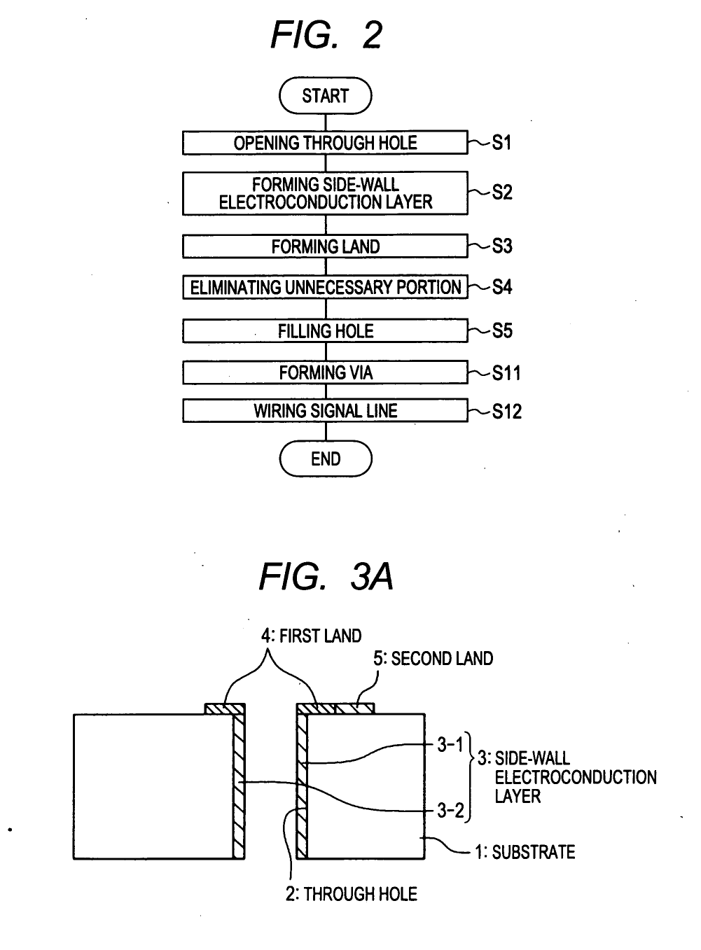

FIG. 2 is a flow chart showing the method of manufacturing the wiring substrate according to the first embodiment of the invention. When a semiconductor chip is mounted on or above the substrate 1, FIG. 2 shows process steps for manufacturing the semiconductor device.

### (Step S1: Through Hole Opening Step)

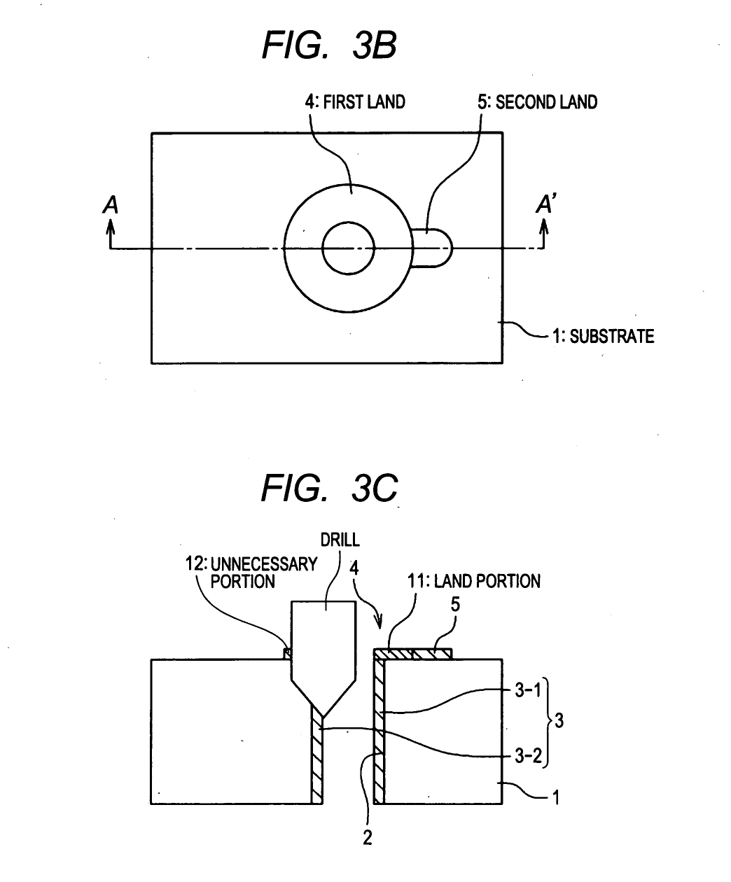

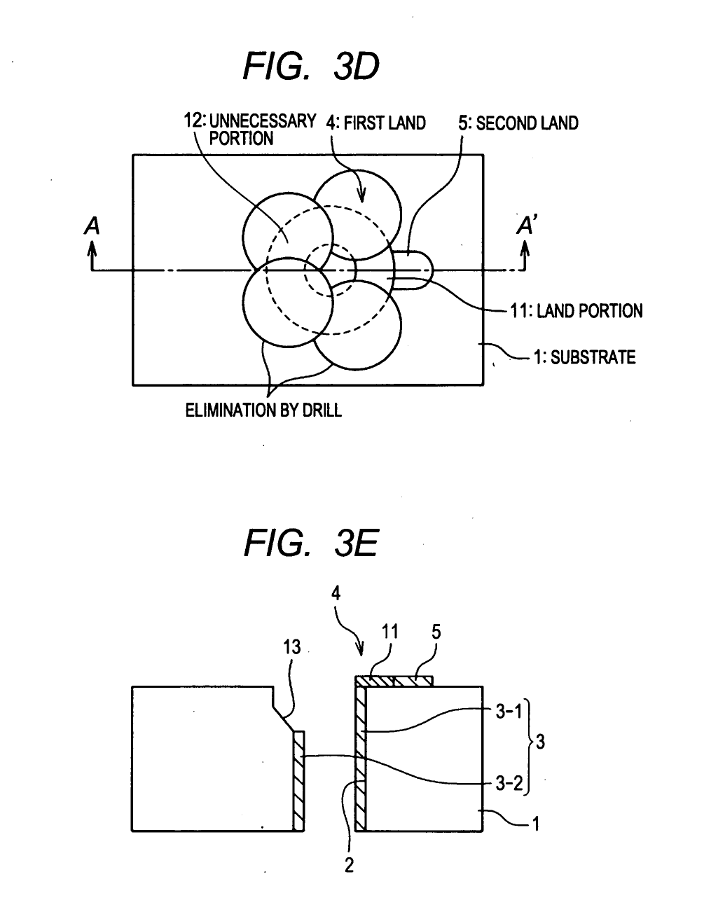

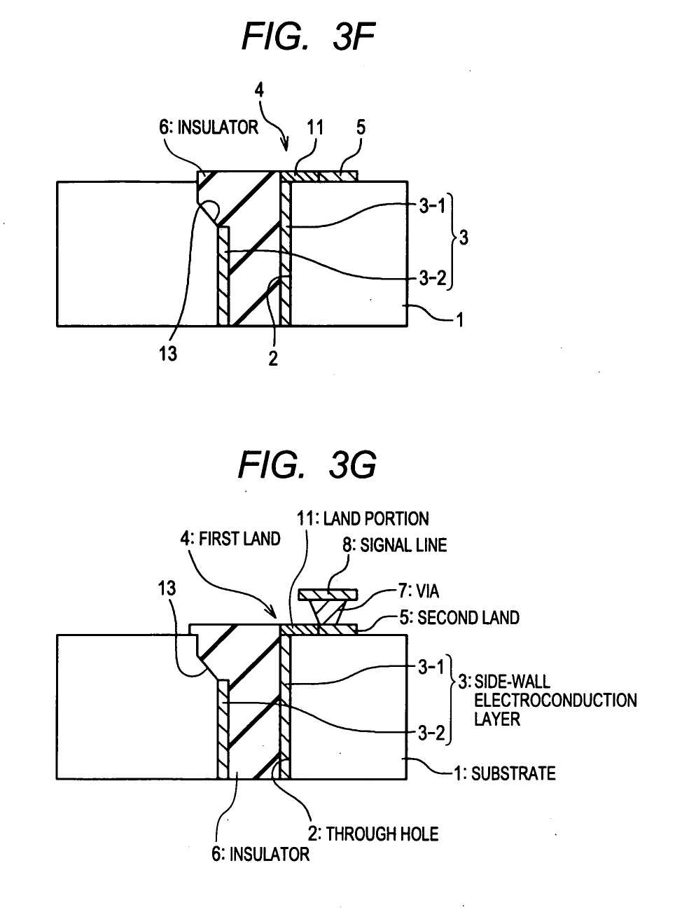

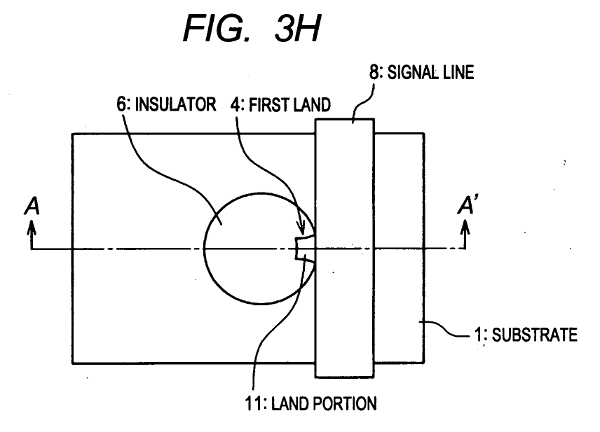

At first, as shown in FIG. 3A, a substrate 1 is provided. A through hole 2 is opened in the substrate 1.

### (Step S2: Side-Wall Electroconduction Layer Formation Step)

Then, as shown in FIG. 3A, a side-wall electroconduction layer 3 is formed as an electroconduction layer that extends along the side-wall of the through hole 2. For example, a metal such as copper or aluminum is used for the side-wall electroconduction layer 3.

### (Step 3: Land Formation Step)

Then, as shown in FIG. 3A and FIG. 3B, a first land 4 as an electroconduction layer connected with the side-wall electroconduction layer 3 and a second land 5 as an electroconduction layer connected with the first land 4 are formed on the surface of the substrate 1. For example, a metal such as copper or aluminum is used for the first land 4 and the second land 5.

### (Step S4: Unnecessary Portion Elimination Step)

Then, as shown in FIG. 3C, unnecessary portion 12 of the first land 4 except for the land portion 11 is eliminated by the operation of a drill. The land portion 11 is a necessary and minimum portion of the first land 4 to be used for wiring and connected with the second land 5. The unnecessary portion 12 is a portion of the first land 4 that is not used for wiring. In the example shown in FIG. 3D, the unnecessary portion 12 is eliminated by operating the drill for 4 times while displacing the position of the drill.

As shown in FIG. 3E, when the unnecessary portion 12 is eliminated by the drill, the substrate 1 is scraped off and, at the same time, a portion of the side-wall electroconduction layer 3 in contact with the unnecessary portion 12 is scraped off. In this case, the side-wall electroconduction layer 3 comprises a first side-wall electroconduction layer 3-1 and a second side-wall electroconduction layer 3-2 connected with the first side-wall electroconduction layer 3-1. The first side-wall electroconduction layer 3-1 reaches the surface of the substrate 1 and connected with the land portion 11. The second side-wall electroconduction layer 3-2 is formed when the portion in contact with the unnecessary portion is eliminated. Accordingly, the second side-wall electroconduction layer 3-2 does not reach the surface of the substrate 1.

In this embodiment, while the unnecessary portion 12 and the portion of the side-wall electroconduction layer 3 in contact with the unnecessary portion 12 are eliminated by a drill, they may be eliminated also by the etching or laser fabrication.

### (Step S5: Hole Filling Step)

Then, as shown in FIG. 3F, when the unnecessary portion 12 is eliminated by the drill, the scraped portion 13 of the substrate 1 is formed. An insulator 6 as a resin is filled in contact with the scraped portion 13, the second side-wall electroconduction layer 3-2, and the first side-wall electroconduction layer 3-1. Thus, the first side-wall electroconduction layer 3-1, the second side-wall electroconduction layer 3-2, and the scraped portion 13 of the substrate 1 are covered with the insulator 6.

### (Step S11: Via Forming Step)

Then, as shown in FIG. 3G, the via 7 is formed over the second land 5. In FIG. 3G, the insulator layer is not illustrated in the same manner as in FIG. 1B.

### (Step S12: Signal Line Wiring Step)

Then, as shown in FIG. 3G, a signal line 8 is formed over the via 7. After the step S12, a semiconductor chip may be mounted on or above the substrate 1 or the wiring substrate.

By the steps described above, a structure of FIG. 1A can be obtained. The structure is not restricted to that shown in FIG. 1A but may be formed, for example, as shown in FIG. 3H. In this case, the structure shown in FIG. 3H can be obtained by cutting out the unnecessary portion 12 while displacing the position of the drill little by little in the unnecessary portion elimination step in step S4. Also in this case, the cross section along A-A′ in FIG. 3H is as shown in FIG. 3E to FIG. 3G.

### [Function 1-1]

The reason for practicing the unnecessary portion elimination step (step S4) is to be described.

When signals are transmitted at a high speed by way of a signal line, it has to be taken into consideration not only the reflection of the signals but also the rising (or falling) speed upon switching of a signal level. The signal rising (or falling) speed is physically determined by “time constant” represented by a multiplication product of a wiring resistance R and a wiring capacitance C. Accordingly, when it is intended to attain high speed signal transmission, it is necessary to be coped by lowering the wiring resistance or decreasing the wiring resistance. Generally, this is coped by decreasing the wiring capacitance.

For example, in the technique described in Japanese Patent Application Publication No. Hei-10(1998)-51137, and Japanese Patent Application Publication No. Sho-60(1985)-257585, the through hole and the side hole electroconduction layer are divided together with the land in order to attain higher density and higher integration degree of electronic equipment under the condition where the minimum diameter of the land is restricted. However, since the density and the integration degree have been increased further, and the diameter of the through hole has been decreased in recent years, wiring capacitance C cannot be decreased sufficiently by merely dividing the land.

On the contrary, in the wiring substrate according to a first embodiment of the invention, an unnecessary portion 12 of the land 4 other than the land portion 11 is eliminated by practicing the unnecessary portion elimination step (step S4). In the step, an unnecessary wiring capacitance can be decreased from the wiring capacitance due to the land 4 by eliminating the unnecessary portion of the land 4 while leaving only the minimum necessary portion used for wiring.

### [Function 1-2]

The reason why all of the portion of the side-wall electroconduction layer 3 other than the first side-wall electroconduction layer 3-1 (second side-wall electroconduction layer 3-2) connected to the land portion 11 are not eliminated in the unnecessary portion elimination step (S-4) will be explained.

At first, in the technique described in Japanese Patent Application Publication No. Hei-10(1998)-51137 and Japanese Patent Application Publication No. Sho-60(1985)-257585, the side-wall electroconduction layer is divided into two or more blocks when the through hole and the side-wall electroconduction layer are divided together with the land. In this case, a surplus capacitance is generated between the blocks.

On the other hand, in the wiring substrate according to the first embodiment of the invention, a portion of the side-wall electroconduction layer 3 in contact with the unnecessary portion 12 is eliminated by practicing the unnecessary portion elimination step (step S4). In this step, no surplus capacitance is generated to the side-wall electroconduction layer 3 by scraping off only the portion of the side-wall electroconduction layer 3 in contact with the unnecessary portion 12 and not dividing the side-wall electroconduction layer 3.

### [Effect 1]

As described above, in the wiring substrate according to the first embodiment of the invention, unnecessary wiring capacitance in the wiring capacitance due to the land 4 can be decreased and no surplus capacitance to the side-wall electroconduction layer 3 is generated by practicing the unnecessary portion elimination step (step S4). Since this can decrease the time constant sufficiently and increase the signal rising (or falling) speed, signal can be transmitted at a higher speed.

### Second Embodiment

In a case where a signal line is present over the insulator 6, the wiring capacitance is changed. Then, in the wiring substrate according to the second embodiment of the invention, a step of disposing a plane for shielding, etc. are added after the hole filling step (step S5) in the first embodiment. For the second embodiment, duplicate description with the first embodiment is to be omitted.

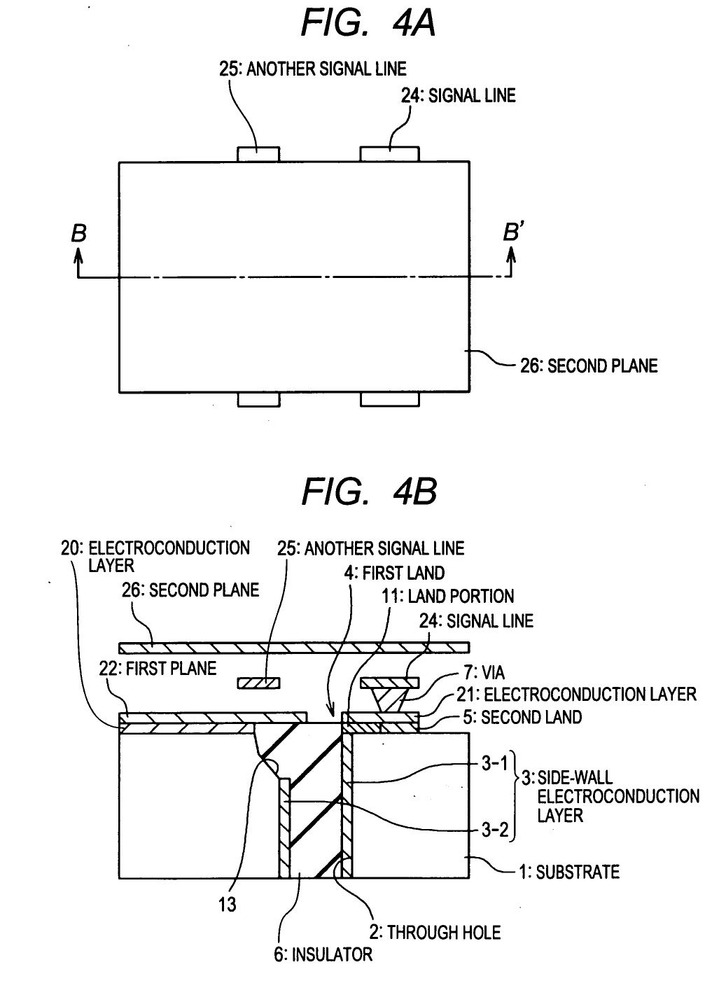

FIG. 4A is an upper plan view showing the configuration of the wiring substrate according to the second embodiment of the invention. FIG. 4B is a cross sectional view along line B-B′ in FIG. 4A. A wiring substrate according to the second embodiment of the invention includes a substrate 1, a side-wall electroconduction layer 3, a first land 4, a second land 5, an insulator 6, electroconduction layers 20, 21, a first plane 22, a via 7, a signal line 24, another signal line 25, and a second plane 26. That is, the wiring substrate according to the second embodiment of the invention has the electroconduction layers 20, 21, the first plane 22, the signal line 24, another signal line 25, and the second plane 26 instead of the signal line 8 in the first embodiment. In FIG. 4B, an insulation layer present between the substrate 1 and the second plane 26 is not illustrated.

The electroconduction layer 21 is formed over the land portion 11 and the second land 5.

The first plane 22 is a wiring layer for shielding formed over the substrate 1 (that is, over the electroconduction layer 20) and over the insulator 6.

The via 7 is formed over the electroconduction layer 21, and the signal line 24 is formed over the via 7. Another signal line 25 is formed over the plane 22.

The second plane 26 is a wiring layer for shielding formed over the signal line 24 and another signal line 25.

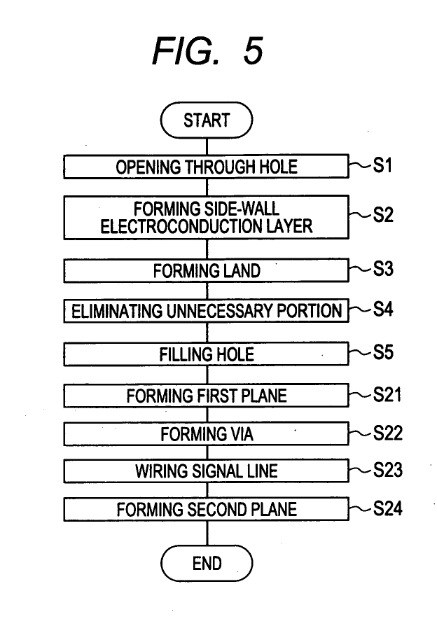

FIG. 5 is a flow chart showing the method of manufacturing the wiring substrate according to the second embodiment of the invention.

### (Step S1: Through Hole Opening Step)

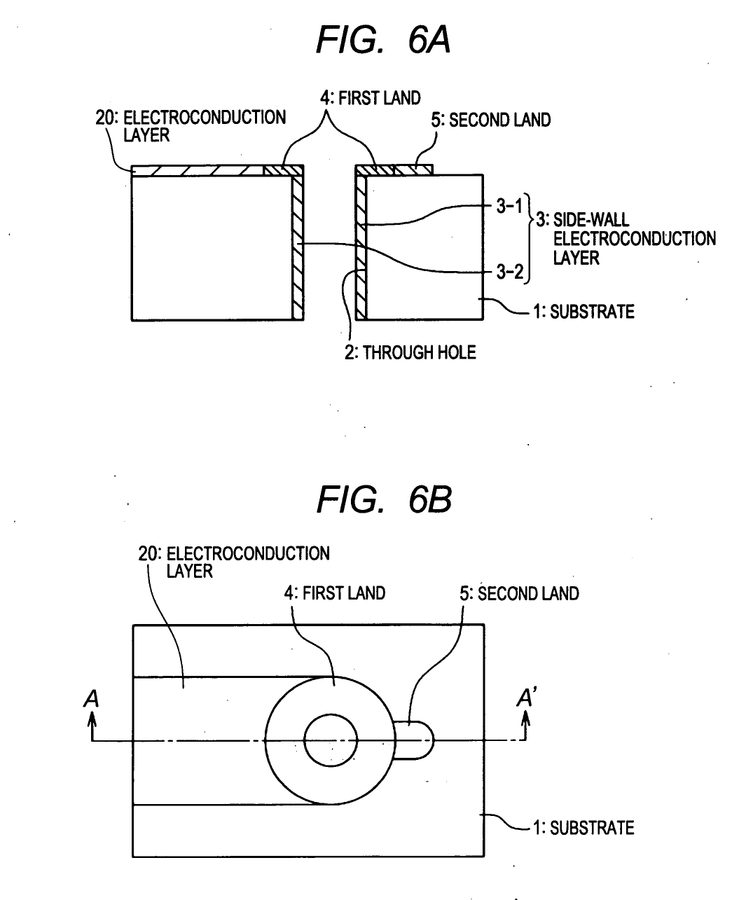

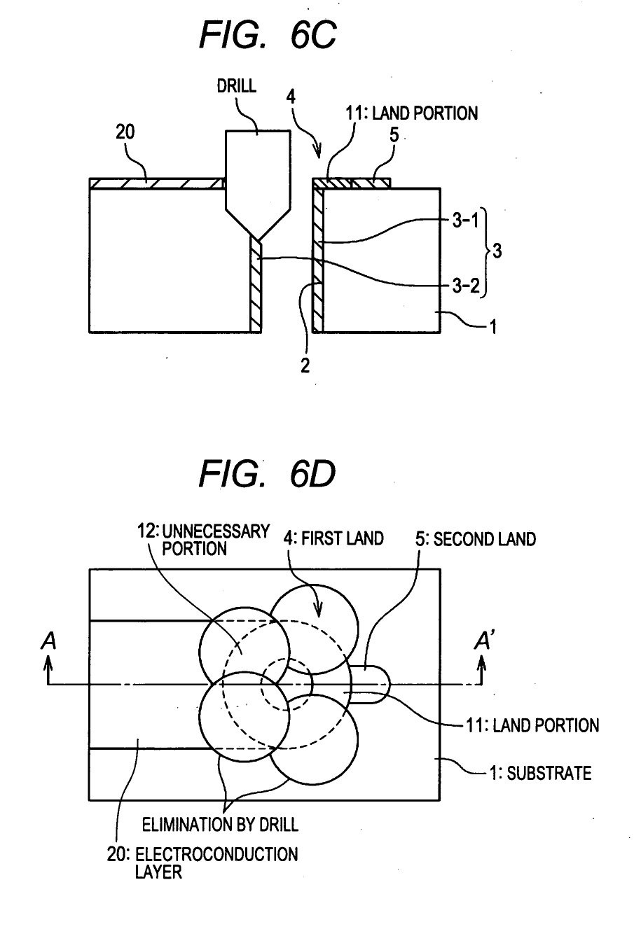

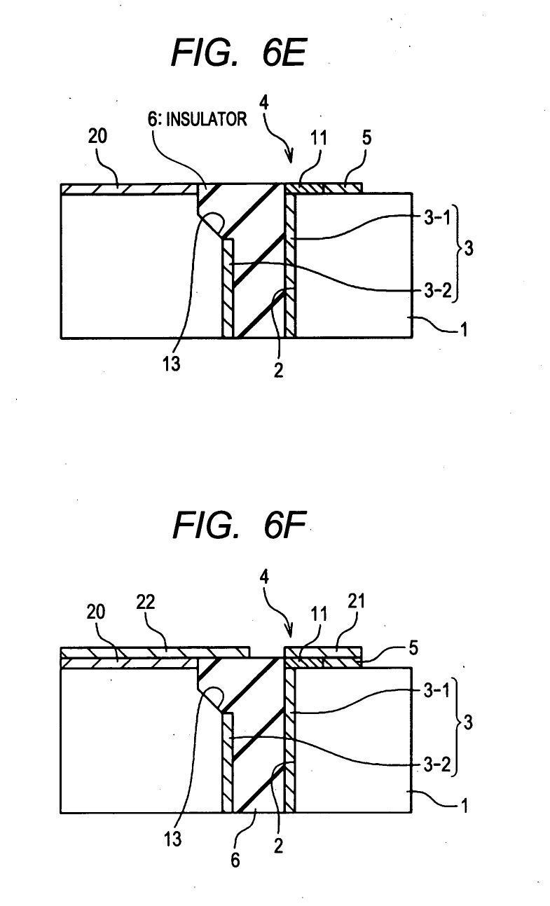

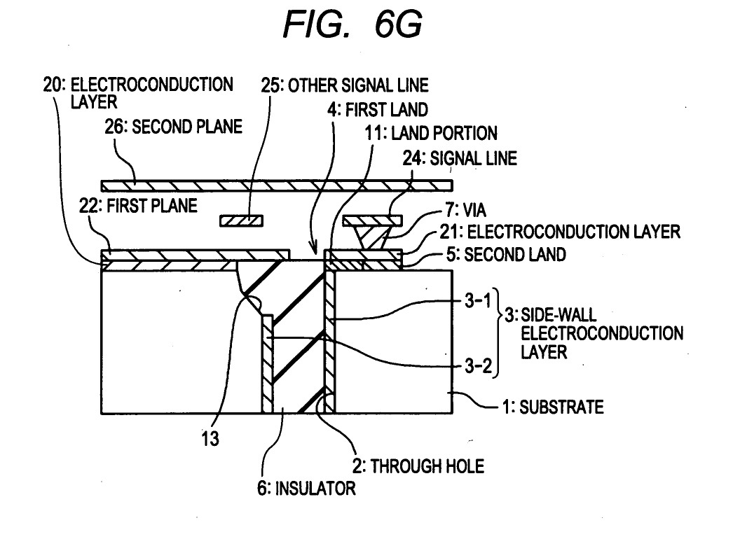

At first, as shown in FIG. 6A, a substrate 1 is provided. A through hole 2 is apertured in the substrate 1.

### (Step S2: Side-Wall Electroconduction Layer Formation Step)

Then, as shown in FIG. 6A, a side-wall electroconduction layer 3 as an electroconduction layer is formed on the through hole 2.

### (Step S3: Land Formation Step)

Then, as shown in FIG. 6A and FIG. 6B, a first land 4 connected with the side-wall electroconduction layer 3 and a second land 5 connected with the first land 4, and an electroconduction layer connected to the first land 4 are formed to the surface of the substrate 1. For example, a metal such as copper or aluminum is used as the conductive layer 20.

### (Step S4: Unnecessary Portion Elimination Step)

Then, as shown in FIG. 6C, unnecessary portion 12 of the first land 4 other than the land portion 11 is eliminated by operating a drill. The land portion 11 is a minimum necessary portion of the first land 4 to be used for wiring and connected with the second land 5. The unnecessary portion 12 is a portion of the first land 4 not used for wiring and connected to the electroconduction layer 20. In the example shown in FIG. 6D, the unnecessary portion 12 is eliminated by operating the drill for 4 times while displacing the position of the drill.

As shown in FIG. 6E, when the unnecessary portion 12 is eliminated by the drill, the substrate 1 is scraped off and, at the same time, a portion of the side-wall electroconduction layer 3 in contact with the unnecessary portion 12 is scraped off. In this case, the side-wall electroconduction layer 3 comprises a first side-wall electroconduction layer 3-1 and a second side-wall electroconduction layer 3-2 connected with the first side-wall electroconduction layer 3-1. The first side-wall electroconduction layer 3-1 reaches the surface of the substrate 1 and is connected with the land portion 11. The second side-wall electroconduction layer 3-2 is formed when the portion in contact with the unnecessary portion is eliminated. Accordingly, the second side-wall electroconduction layer 3-2 does not reach the surface of the substrate 1.

In this embodiment, while the unnecessary portion 12 and the portion of the side-wall electroconduction layer 3 in contact with the unnecessary portion 12 are eliminated by drill, they may be eliminated also by etching or laser fabrication.

### (Step S5: Hole Filling Step)

Then, as shown in FIG. 6E, when the unnecessary portion 12 is eliminated by the drill, a portion 13 where the substrate 1 is scraped off is formed. The portion 13 is in contact with the second side-wall electroconduction layer 3-2 and exposed together with the first side-wall electroconduction layer 3-1 and the second side-wall electroconduction layer 3-2. Accordingly, an insulator 6 which is a resin is formed over the first side-wall electroconduction layer 3-1, the second side-wall electroconduction layer 3-2, and the portion 13 where the substrate 1 is scraped off. Thus, the first side-wall electroconduction layer 3-1, the second side-wall electroconduction layer 3-2, and the portion 13 where the substrate 1 is scraped off are covered with the insulator 6.

### (Step S21: First Plane Formation Step)

Then, as shown in FIG. 6F, a first plane 22 for shielding is formed the substrate 1 (that is, on the electroconduction layer 20) and over the insulator 6. In this case, an electroconduction layer 21 is formed over the land portion 11 and the second land 5 for aligning the height with the first plane 22. For example, a metal such as copper or aluminum is used for the electroconduction layer 21 and the plating is used for the first plane 22.

### (Step S22: Via Forming Step)

Then, as shown in FIG. 6G, a via 7 is formed over the electroconduction layer 21.

### (Step S23: Signal Line Wiring Step)

Then, as shown in FIG. 6G, a signal line 24 is formed over the via 7. Another signal line 25 is formed by way of a first insulation layer (not illustrated) over the first plane 22.

### (Step S24: Second Plane Formation Step)

Then, as shown in FIG. 6G, a second plane 26 for shielding is formed by way of a second insulation layer (not illustrate) over the signal 24 and another signal line 25. For example, plating is used for the second plane 26.

### [Function 2]

A reason for practicing the first plane formation step (step S21) is to be described.

Generally, when a plane is present just below the signal line, a return path (feedback current path) is formed in the portion. However, when a signal line is present above an insulator formed over the side-wall electroconduction layer, since the plane is not present for the portion, the feedback current flows along the side-wall electroconduction layer just below the insulator. Therefore, the characteristic of the signal line changes by so much as the portion. Particularly, in a case of a high speed signal, the wiring capacitance may sometimes be changed by merely conducting wiring while overriding the insulator by about three times and the signal characteristic of high speed signals cannot some times be satisfied.

Then, in the technique described in Japanese Patent Application Publication No. 2003-273273, an ideal signal characteristic is attained by changing the thickness of the insulator layer (corresponding to first and second insulation layers in the examples described above).

On the contrary, in the wiring substrate according to the second embodiment of the invention, by practicing the first plane formation step (step S21), a portion above the substrate 1 (on the electroconduction layer 20) and the insulator 6 are covered with the first plane 22 so as to avoid the minimum necessary portion (periphery of the land portion 11) that has to be connected electrically with the side-wall electroconduction layer 3. In this step, since the area covered by the plane (plane area) relative to the side-wall electroconduction layer 3 just below the insulator 6 extends, the wiring capacitance can be maintained as it is and the signal characteristic of the high speed signals can be satisfied even when the signal line is present above the insulator 6.

Further, in the wiring substrate according to the second embodiment of the invention, since the portion above the substrate 1 (on the electroconduction layer 20) and the insulator 6 are covered with the first plane 22, an ideal signal characteristic can be attained even when the thickness of the first and the second insulator layers is not changed.

### [Effect 2]

As described above, the wiring substrate according to the second embodiment of the invention can satisfy the signal characteristic of high speed signals in addition to the effect of the first embodiment by practicing the first plane formation step (step S21) also in a case where the signal line is wired over the insulator 6. Therefore, since the size of the first land is reduced and the plane area is extended, the density of signal lines that can be wired in the area is increased and a product of a smaller size can be prepared.

### Third Embodiment

In a wiring substrate according to a third embodiment of the invention, a signal line is wired over the substrate 1 not over the via 7 for manufacture at a lower cost relative to the first embodiment. In the third embodiment, duplicate description with the first and the second embodiments is to be omitted.

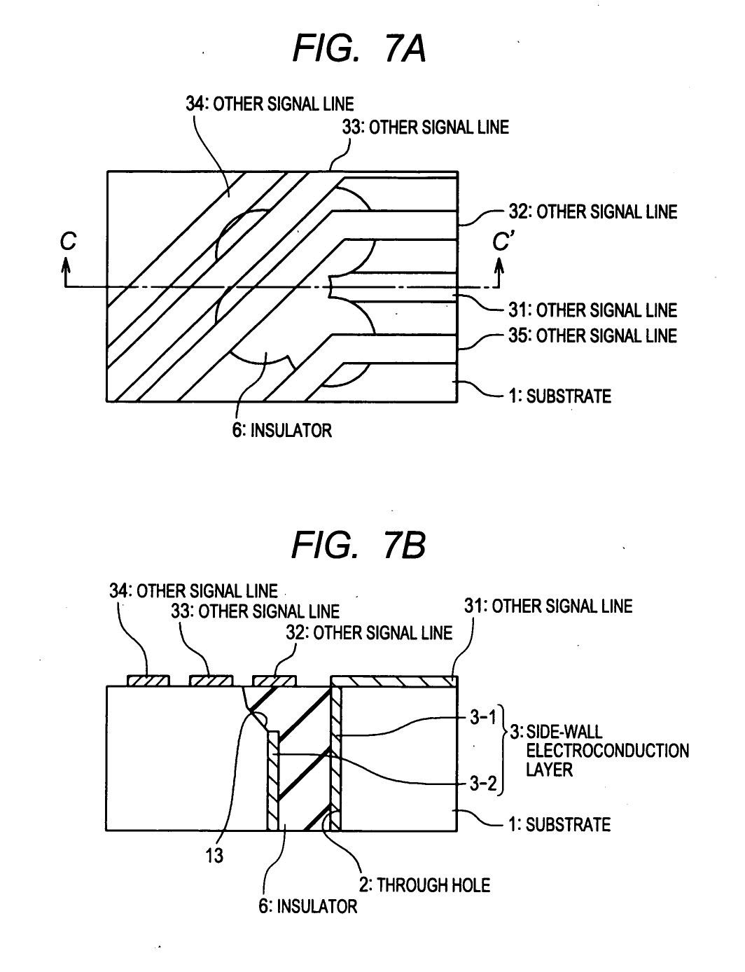

FIG. 7A is an upper plan view showing the configuration of the wiring substrate according to the third embodiment of the invention. FIG. 7B is a cross sectional view along line C-C′ of FIG. 7A. A wiring substrate according to the third embodiment of the invention includes a substrate 1, a side-wall electroconduction layer 3, a first land 4 (hereinafter referred to as a land 4), an insulator 6, a signal line 31, and other signal lines 32 to 35. That is, the wiring substrate according to the third embodiment includes a signal line 31 and other signal lines 32 to 35 instead of the second land 5, the via 7, and the signal line 8 in the first embodiment.

The signal line 31 is formed on the surface of the substrate 1 and connected to the side-wall electroconduction layer 3.

Other signal lines 32 to 35 are formed to the surface of the insulator 6 and the surface of the substrate 1.

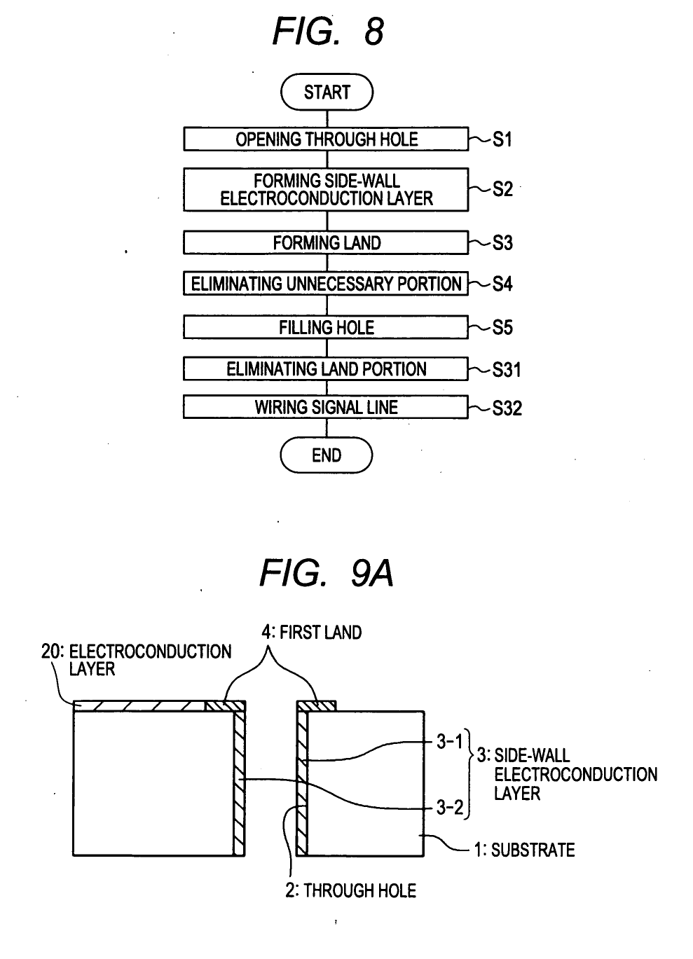

FIG. 8 is a flow chart showing the method of manufacturing the wiring substrate according to the third embodiment of the invention.

### (Step S1: Through Hole Opening Step)

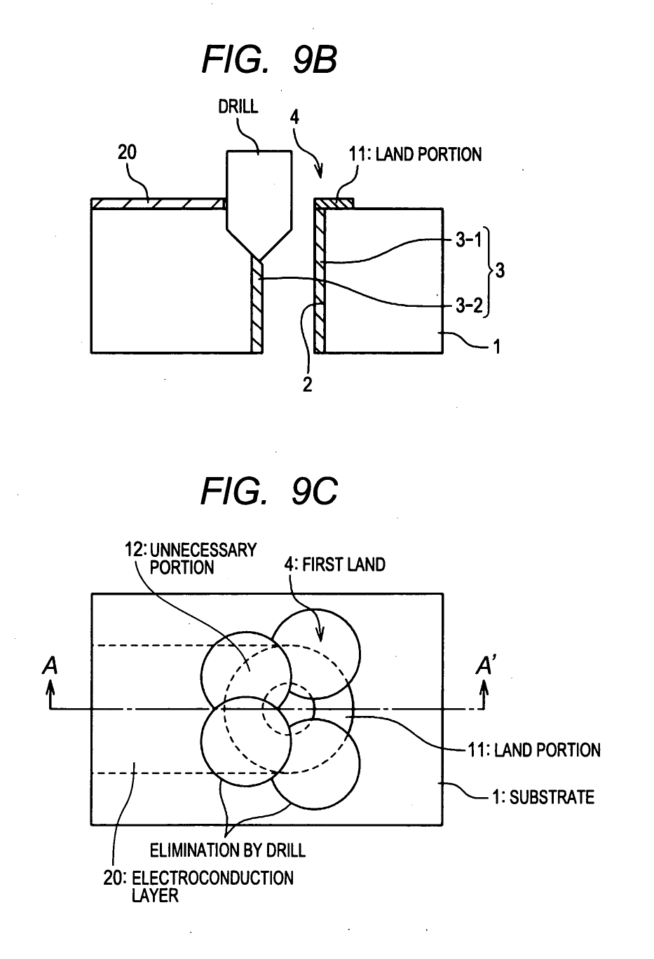

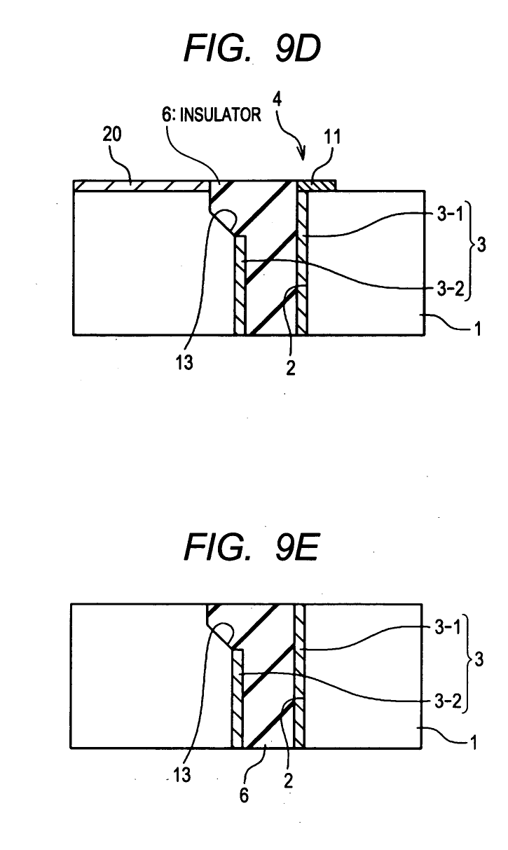

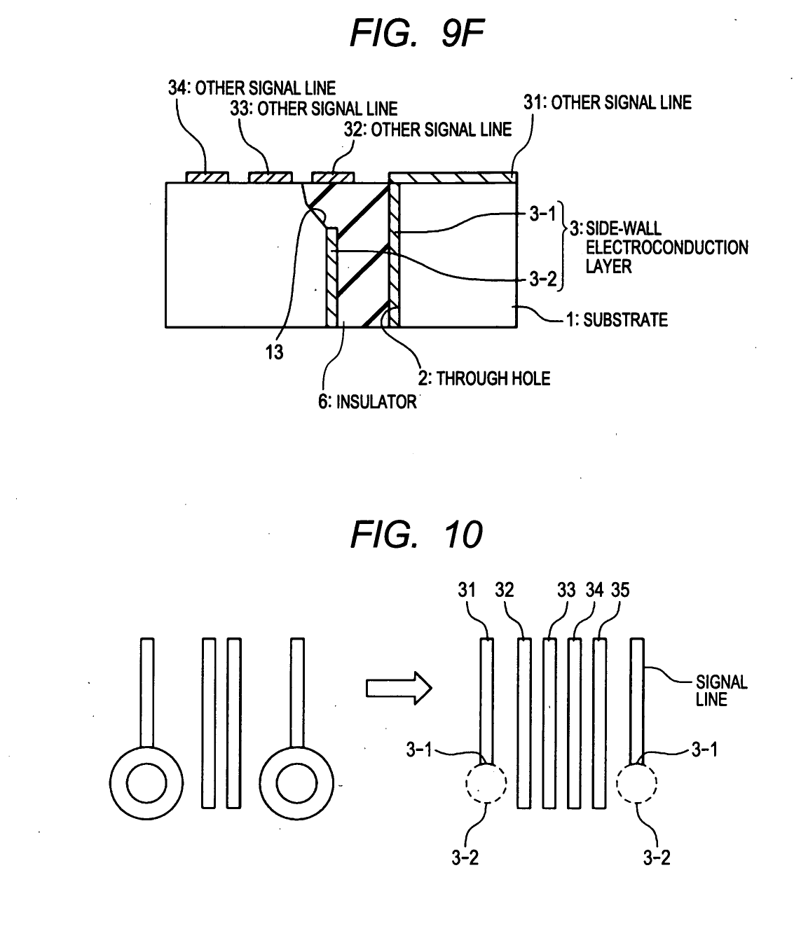

At first, as shown in FIG. 9A, a substrate 1 is provided. A through hole 2 is opened in the substrate 1.

### (Step S2: Side-Wall Electroconduction Layer Formation Step)

Then, as shown in FIG. 9A, a side-wall electroconduction layer 3 as an electroconduction layer is formed on the side-wall of the through hole 2.

### (Step S3: Land Formation Step)

Then, as shown in FIG. 9A, a land 4 connected with the side-wall electroconduction layer 3 and an electroconduction layer 20 connected with the land 4 are formed to the surface of the substrate 1.

### (Step S4: Unnecessary Portion Elimination Step)

Then, as shown in FIG. 9B, an unnecessary portion 12 of the land 4 other than the land portion 11 is eliminated by operating a drill. The land portion 11 is a minimum necessary portion of the land 4 to be used for wiring. The unnecessary portion 12 is a portion of the first land 4 not used for wiring and connected with the electroconduction layer 20. In the example shown in FIG. 9C, the unnecessary portion 12 is eliminated by operating the drill by 4 times while displacing the position.

As shown in FIG. 9D, when the unnecessary portion 12 is scraped off by the drill, the substrate 1 is scraped off and, at the same time, a portion of the side-wall electroconduction layer 3 in contact with the unnecessary portion 12 is scraped off. In this case, the side-wall electroconduction layer 3 comprises a first side-wall electroconduction layer 3-1, a second side-wall electroconduction layer 3-2 connected with the first side-wall electroconduction layer 3-1. The first side-wall electroconduction layer 3-1 reaches the surface of the substrate 1 and is connected with the land portion 11. The second side-wall electroconduction layer 3-2 is formed when the portion in contact with the unnecessary portion is eliminated. Accordingly, the second side-wall electroconduction layer 3-2 does not reach the surface of the substrate 1.

In this embodiment, while the unnecessary portion 12 and the portion of the side-wall electroconduction layer 3 in contact with the unnecessary portion 12 are eliminated by drill, they may be eliminated also by etching.

### (Step S5: Hole Filling Step)

Then, as shown in FIG. 9D, when the unnecessary portion 12 is eliminated by the drill, the scraped portion 13 of the substrate 1 is formed. The portion 13 is in contact with the second side-wall electroconduction layer 3-2 and exposed together with the first side-wall electroconduction layer 3-1 and the second side-wall electroconduction layer 3-2. Therefore, an insulator 6 which is a resin is formed over the first side-wall electroconduction layer 3-1, the second side-wall electroconduction layer 3-2, and a portion 13 where the substrate 1 is scraped off. Thus, the first side-wall electroconduction layer 3-1, the second side-wall electroconduction layer 3-2, and a portion 13 where the substrate 1 is scraped off are covered with the insulator 6.

### (Step S31: Land Portion Elimination Step)

Then, as shown in FIG. 9E, the electroconduction layer 20 and the land portion 11 are eliminated by grinding.

### (Step S32: Signal Line Wiring Step)

Then, as shown in FIG. 9F, a signal line 31 connected with the first side-wall electroconduction layer 3-1 is formed to the surface of the substrate 1. Other signal lines 32 to 24 are formed to the surface of the insulator 6 and the surface of the substrate 1.

While this embodiment adopts, a wiring system in which a pattern is formed over the substrate 1, but an embedded type wiring system, for example, of digging a trench to the surface of the substrate 1 by laser or the like and forming a pattern therein may also be adopted.

### [Function 3]

The reason for practicing the land portion elimination step (step S31) and the signal wiring step (step S32) is to be described.

Generally, since the diameter of the land is larger by several times or more compared with the width of the signal line, the wiring density cannot be increased so much when wiring is conducted in a layer where the land is present.

On the contrary, in the wiring substrate according to the third embodiment of the invention, the unnecessary portion 12 in the land 4 is eliminated by practicing the unnecessary portion elimination step (step S4) and the portion of the side-wall electroconduction layer 3 in contact with the unnecessary portion 12 is eliminated. Then, the land portion 11 is eliminated to form the signal line 31 connected with the first side-wall electroconduction layer 3-1 by practicing the land portion elimination step (S31) and the signal line wiring step (S32). In this case, as shown in FIG. 10, in a case where wiring for the signal line 31 and other signal lines 32 to 35 is conducted in an identical layer, the distance between the signal line 31 and other signal lines 32 to 35 can be made narrower than the radius of the land.

### [Effect 3]

As has been described above, the wiring substrate according to the third embodiment of the invention can increase the wiring density in addition to the effect of the first embodiment by conducting the land portion elimination step (step S31) and the signal line wiring step (step S32). This can form a pattern at a higher density and also further decrease the size of products.

It is apparent that the present invention is not limited to the above embodiments, and the embodiments can be modified and changed as appropriate within the scope of the technical concept of the present invention.

What is claimed is:

1. A wiring substrate comprising:
a side-wall electroconduction layer being an electroconduction layer formed on a side wall of a through hole opened in a substrate; and
a land being an electroconduction layer connected with the side-wall electroconduction layer and formed on a surface of the substrate,
wherein the side-wall electroconduction layer includes:
a first side-wall electroconduction layer extending along the side-wall of the through hole, reaching the surface of the substrate, and being connected with the land, and
a second side-wall electroconduction layer being connected with the first side-wall electroconduction layer, extending along the side-wall of the through hole and not reaching the surface of the substrate.

2. The wiring substrate according to claim 1, further comprising:
an insulator covering the side-wall electroconduction layer.

3. The wiring substrate according to claim 2, further comprising:
a via formed on the land; and
a first signal line formed on the via.

4. The wiring substrate according to claim 3, further comprising:
a first plane for shielding formed over the substrate and on the insulator.

5. The wiring substrate according to claim 4, further comprising:
a second signal line formed over the first plane; and
a second plane for shielding formed over the first signal line and the second signal line.

6. The wiring substrate according to claim 1, further comprising:
a semiconductor chip being mounted on the substrate.

7. A semiconductor device comprising:
the wiring substrate according to claim 1;
a semiconductor chip being mounted on the wiring substrate.

8. A method of manufacturing a wiring substrate comprising:
opening a through hole in a substrate;
forming a side-wall electroconduction layer which is an electroconduction layer on the side-wall of the through hole;
forming a land which is an electroconduction layer connected with the side-wall electroconduction layer to the surface of the substrate; and
eliminating an unnecessary portion not used for the wiring of the land and a portion of the side-wall electroconduction layer in contact with the unnecessary portion,
wherein a first side-wall electroconduction layer that extends along the side-wall of the through hole, reaches the surface of the substrate, and is connected with the land, and
wherein a second side-wall electroconduction layer that is connected with the first side electroconduction layer, extends along the side-wall of the through hole, and does not reach the surface of the substrate are formed on the side-wall electroconduction layer, by the elimination step.

9. The method of manufacturing a wiring substrate according to claim 8, further comprising:
covering the side-wall electroconduction layer with an insulator.

10. The method of manufacturing a wiring substrate according to claim 8, further comprising:
forming a via over the land; and
forming a signal line over the via.

11. The method of manufacturing a wiring substrate according to claim 8, further comprising:
forming first plane for shielding over the substrate and the insulator.

12. The method of manufacturing a wiring substrate according to claim 8, further comprising:
forming other signal lines over the first plane; and
forming a second plane for shielding over the signal line and said other signal lines.
